(19) United States
(12) Patent Application Publication
(10) Pub. No.: US 2002/0191538 A1
(43) Pub. Date: Dec. 19, 2002

(54) Bi-directional line switched ring with uninterrupted service restoration

(76) Inventor: Takeshi Ono, Kawasaki (JP)

Correspondence Address: Katten Muchin Zavis Rosenman, 575 Madison Avenue, New York, NY, 10022-2585, US

(21) Appl. No.: 10/209,296

(22) Filed: Jul. 31, 2002

Related U.S. Application Data
(63) Continuation of application No. PCT/JP00/00917, filed on Feb. 18, 2000.

(51) Int. Cl. G01R 31/00; G06F 11/00; G08C 15/00

(52) U.S. Cl. 370/222; 370/217; 359/119

(57) ABSTRACT

In a switching method for an optical ring system, a non-interruption path extending from an add node to a drop node is established along a currently working line, and a fault bypass backup path extending from the add node to the drop node is established along a protection line running in the opposite direction from the currently working line. Signals received at the add node are added to both the currently working line and the protection line. It is determined whether a failure detected in the ring is relevant to the non-interruption path, and the signal is continuously added to the protection line if the failure is relevant to the non-interruption path. If the failure is irrelevant to the non-interruption path, then a return path entering the add node along the protection line is allowed to pass through the add node, instead of adding the signal to the protection line.

### CROSS REFERENCE

This patent application is a continuation application based on PCT/JP00/00917 filed Feb. 18, 2000, the entire contents of which are incorporated herein by reference.

### BACKGROUND OF THE INVENTION

1. Field of the Invention

The present invention relates to a bi-directional line switched ring system having a service restoration arrangement, and to a path switching method for such a bi-directional line switched ring system.

2. Description of the Related Art

BLSR (Bi-directional Line Switched Ring) is a type of ring network system that utilizes a time slot regularly shared as a primary route by multiple signal paths, and a corresponding time slot is shared as an alternate, spare route (or a secondary route) by the multiple signal paths only as needed. This type of ring network system can achieve high line-accommodation efficiency.

FIG. 1 illustrates an example of the conventional BLSR. Path 1 between the nodes 1 and 2, path 2 between the nodes 2 and 3, path 3 between the nodes 3 and 4, and path 4 between the nodes 4 and 1 utilize in common a time slot on line R1 (i.e., currently working line) as a primary route. These paths also utilize in common a corresponding time slot on line 2 (i.e., protection line) as an alternate, spare route.

To avoid service interruption due to a failure that occurs somewhere on the BLSR, a loop-back switching arrangement illustrated in FIG. 2 has been proposed. In FIG. 2, originating node 1 gives a phase identifier to a signal, and transmits the signal with a phase identifier to the primary and secondary routes at the same time. A terminating node absorbs the phase difference of the two routes at its memory and matches the phases with each other to carry out loop-back switching. BLSR with a loop-back switching application can restores the service without interruption even if a failure occurs on the ring, and it satisfies both line accommodation efficiency and line reliability simultaneously.

However, the BLSR system shown in FIG. 2 is unsuitable for practical use because it requires a large memory capacity to conduct the loop-back switching, where a failure on a path is detected, and then, the signal is returned back to the alternate (secondary) route before the failure detection point.

In BLSR, if a failure occurs between node 2 and node 3, for example, on path A extending from node 1 via nodes 2 and 3 toward node 4, then the bridging operation shown in FIG. 3(A) is carried out at node 2, and the switching operation shown in FIG. 3(B) is carried out at node 3. At node 2, the bridge circuit returns the signal back to the protection line P running in the opposite direction from the currently working line W. In this case, the signal reaches node 3 following path A′ (node 1→node 2→node 1→node 4→node 3). At node 3, the switch circuit switches the route from path A′ to path A so that the signal reaches node 4, avoiding the failure.

One known approach to realizing failure bypass in the conventional BLSR is to provide a phase adjustment function to the switch circuit of node 3, as illustrated in FIG. 4. In FIG. 4, node 3 includes multiframe synchronizing circuits 11 and 12 for the currently working line W and a protection line P, respectively. The synchronizing circuits 11 and 12 detect the multiframe synchronizations of the associated working line W and the protection line P, and supply the detected synchronizations to the delay controller 15. The delay controller 15 controls the amounts of delay of the delay memories 13 and 14 that store the multiframes of the working line W and the protection line P, respectively, based on the detected multiframe synchronizations. Under the control of the delay controller 15, the delay memories 13 and 14 output in-phase multiframes to the switching circuit 16. The switching controller 17 causes the switching circuit 16 to switch the route to an appropriate path.

However, the above-described phase adjustment function implies a requirement for a large loading space because the phase adjustment function has to be furnished to the high-speed unit of each node and, in addition, phase adjustment is required for every time slot. Another problem is a time lag caused by the propagation of failure information. In general, failure is detected by the receiving side (i.e., node 3), as illustrated in FIG. 5(A), and loop-back switching (or failure bypassing) is not carried out until the fault information detected at node 3 is provided to node 2 via the fault notice route. In this example, nodes 2 and 3, between which a failure occurs., function as return control nodes.

Once the failure has been detected, fault information, an example of which is illustrated in FIG. 5(B), is transmitted from node 3 to node 2 via node 4 and node 1, propagating almost around the ring. During the propagation of the failure information, the service is interrupted. To avoid the service interruption, node 2 at which the bridging operation is carried out must return the signal that has been transferred to node 2 before the failure. Accordingly, node 2 needs to have a delay memory 18 (FIG. 6) that can hold the pre-failure signals for a time period corresponding to the propagation of the failure information, as illustrated in FIG. 6.

In addition, the path difference between path A and path A′ must be taken into account when controlling the delay memory 19 of node 3. (The delay memory 19 shown in FIG. 6 corresponds to the delay memory 14 shown in FIG. 4.) The delay memory 19 is controlled so that the phases of the path A and path A′ are consistent with each other, and therefore, the delay memory 19 needs to have a memory capacity that can absorb the lag of at least twice around the ring, which corresponds to the sum of the path difference between path A and path A′ and signal holding at the delay memory 18.

Furthermore, in order to compare the phase differences, synchronization of multiframe identifiers (that indicate a phase difference) has to be accomplished. However, since it is unknown at which point the signal is returned, exact multiframe synchronization cannot be accomplished in advance. Accordingly, three-stage protection for multiframe synchronization is generally given to the memory. This means that the delay memory 19 must have a capacity to absorb the lag of an additional 6 times around the ring, which equals three times the multiframe length (that is generally more than double the maximum ring length).

This six times around the ring lag is added to the path difference (at delay memory 19) and the propagation time (at delay memory 18). Therefore, at least the total of eight times around the ring of lag (which corresponds to 4 multiframes) occurs, as illustrated in FIG. 7.

Thus, in order to realize failure bypass without service interruption in the conventional BLSR, a relatively large capacity of memory is required in the ordinary path. This causes further problems of lading space and technique, undesirable heat generation, increased cost, and increase of signal delay in the normal communication state. Since it is unknown at which point of the ring a failure will occur, delay memories 18, 19 have to be provided at each node. Therefore, the total amount of signal delay becomes the delay of delay memory 19 (i.e., eight times around the ring) multiplied by the number of passing nodes even in the normal communication state, which is unsuitable for practical use in a communication network.

If it takes 5 ns for an optical signal to propagate 1 meter through the optical fiber, and if the length of a ring with 16 nodes is 800 km, then the maximum signal delay in the normal communication state becomes

5 ns×800×100 m×8rounds×(16-1)nodes=480 ms.

Such a large amount of delay can not be neglected because deterioration of line quality due to echo becomes conspicuous. Therefore, a memory that can absorb this amount of delay becomes necessary. In addition, the operation of the ring is apt to be unstable due to variations in control time for the switching sequence and multiframe synchronization time. Eventually, a size of double or triple calculated amount of memory is required in reality in order to guarantee reliable operation.

### SUMMARY OF THE INVENTION

Therefore, it is a general object of the present invention to provide a bidirectional line switching method and a bidirectional line switched ring (BLSR) system that can achieve uninterrupted service restoration while not requiring the memory capacity to increase. To achieve this object, the concept of the UPSR (Unidirectional Path Switched Ring) is merged into the BLSR system.

To achieve the object, in a switching method for an optical ring network, a non-interruption path extending from an add node to a drop node is established along a currently working line, and a fault bypass backup path extending from the add node to the drop node is established along a protection line running in the opposite direction from the currently working line. Signals received at the add node are added to both the currently working line and the protection line. It is determined whether a failure detected in the ring is relevant to the non-interruption path, and the signal is continuously added to the protection line if the failure is relevant to the non-interruption path. In this case, the drop node switches the signal path from the non-interruption path to the fault bypass path without service interruption, and extracts the signal having propagated through the protection line. This path switching conducted at the drop node is unidirectional path switching.

If the failure is irrelevant to the non-interruption path, then a return path entering the add node along the protection line is allowed to pass through the add node, instead of adding the signal to the protection line. In this case, the drop node continuously selects the non-interruption path without switching, while producing the return path for saving the other signal paths. This path switching is bidirectional line switching.

In this manner, a UPSR method and a BLSR method are merged to realize uninterrupted path switching while achieving high reliability and line accommodation efficiency of the optical ring. In addition, the memory capacity of each node can be reduced.

### BRIEF DESCRIPTION OF THE DRAWINGS

Other objects, features, and advantages of the invention will become apparent from the following detailed description when read in conjunction with the accompanying drawings, in which:

FIG. 1 illustrates an example of a BLSR structure;

FIG. 2 illustrates an example of a loop-back switching function;

FIG. 3(A) illustrates a bridging operation at a node in FIG. 2 and FIG. 3(B) illustrates a switching operation at a node in FIG. 2;

FIG. 4 illustrates an example of a node structure that has an uninterrupted switching function;

FIG. 5(A) illustrates propagation of fault information and FIG. 5(B) illustrates an example of fault information;

FIG. 6 is a diagram used to explain necessity of delay memories;

FIG. 7 illustrates the total amount of delay occurring in a conventional service restoration ring;

FIG. 8 illustrates a basic structure of the ring system according to an embodiment of the present invention;

FIG. 9 is a diagram used in explanation of the concept of uninterrupted fault bypass switching according to the invention;

FIG. 10 is another diagram used to explain the concept of uninterrupted fault bypass switching according to the invention;

FIG. 11 is yet another diagram used to explain the concept of uninterrupted fault bypass switching according to the invention;

FIG. 12 illustrates the structure of an add node in the BLSR (bidirectional line switched ring) system according to the first embodiment of the invention;

FIG. 13 illustrates the structure of a drop node in the BLSR system according to the first embodiment of the invention;

FIG. 14 illustrates an example of the add/through determination unit provided to the add node shown in FIG. 12;

FIG. 15(A) illustrates propagation of fault information, FIG. 15(B) illustrates an example of fault information, FIG. 15(C) illustrates an example of node information, and FIG. 15(D) illustrates an example of path information;

FIG. 16 is an operation flow of the fault data analyzer used in the add/through determination unit shown in FIG. 14;

FIG. 17 illustrates a path connection management table;

FIG. 18 illustrates the structure of the drop node according to the second embodiment of the invention;

FIG. 19 illustrates the structure of the drop node according to the third embodiment of the invention;

FIG. 20 illustrates the path switch determination unit provided in the drop node shown in FIG. 19;

FIG. 21 illustrates an operation flow of path switching carried out by the path switch determination unit shown in FIG. 20;

FIG. 22 illustrates the structure of the drop node according to the fourth embodiment of the invention;

FIG. 23 illustrates an operation flow of determination of path switch availability carried out by the switching availability determination unit shown in FIG. 22;

FIG. 24 illustrates an operation flow of switching back to the normal route, which is carried out by the switching controller shown in FIG. 19; and

FIG. 25 illustrates an operation flow of returning the TSA (time slot assignment) to the add mode after restoration of failure according to the invention.

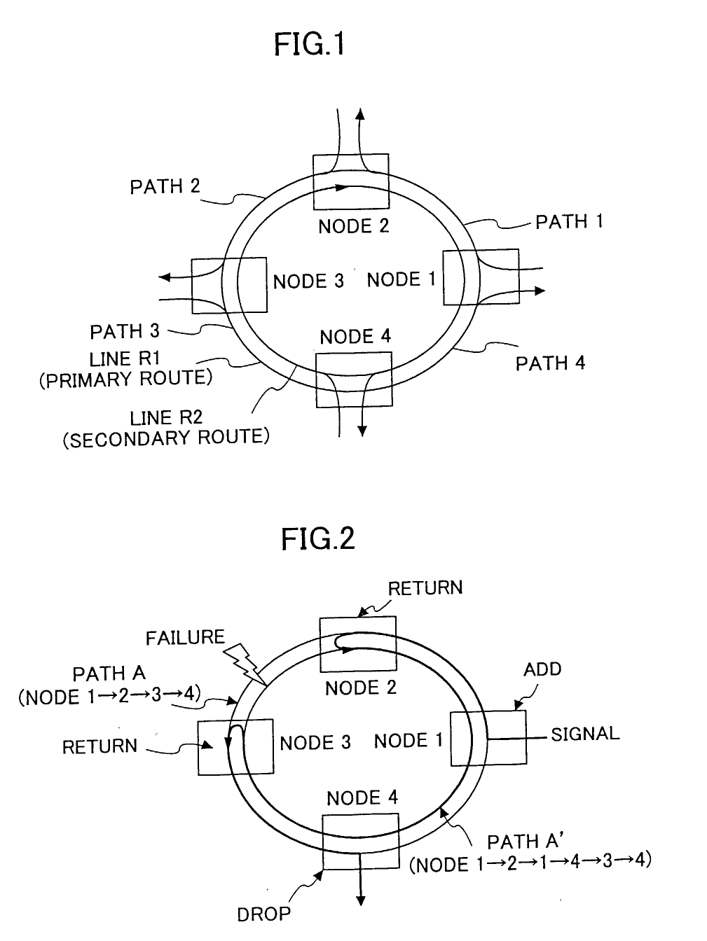

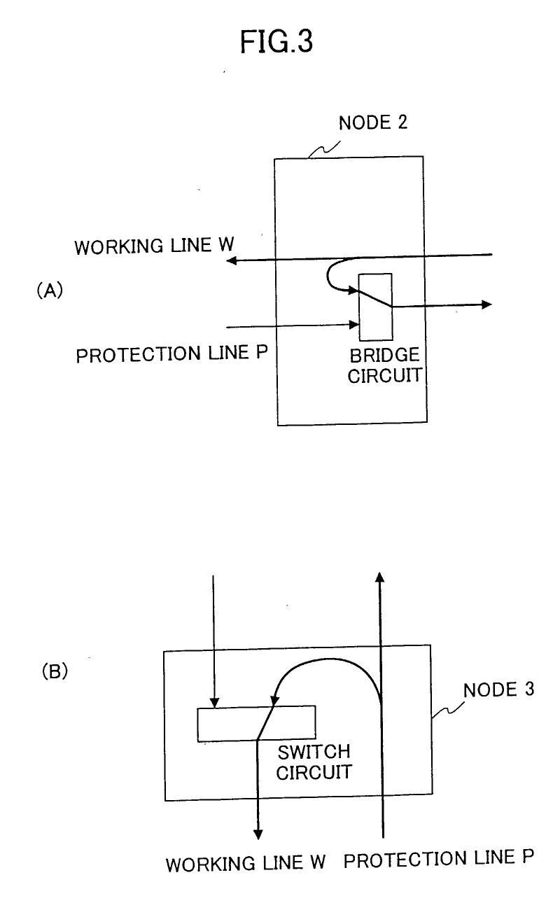

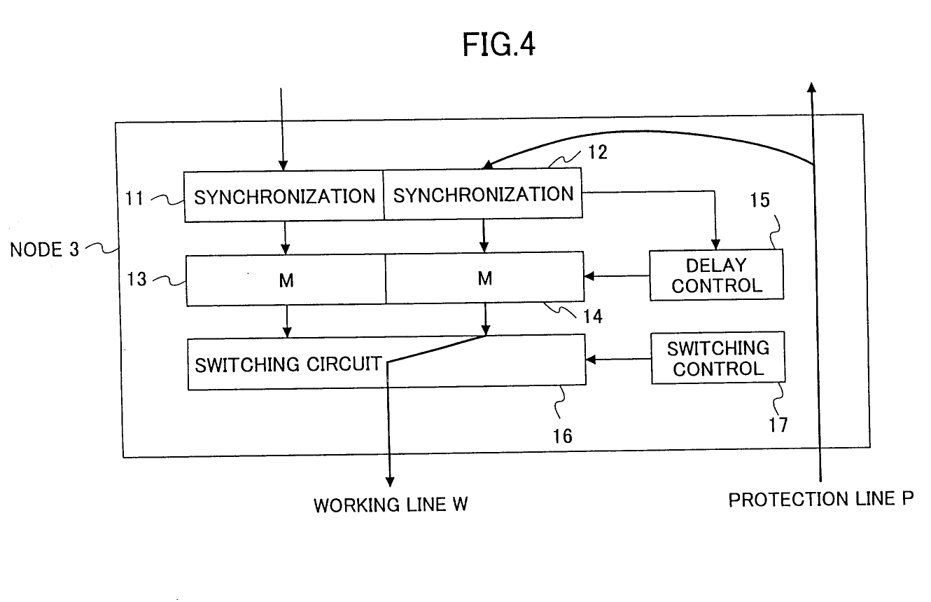

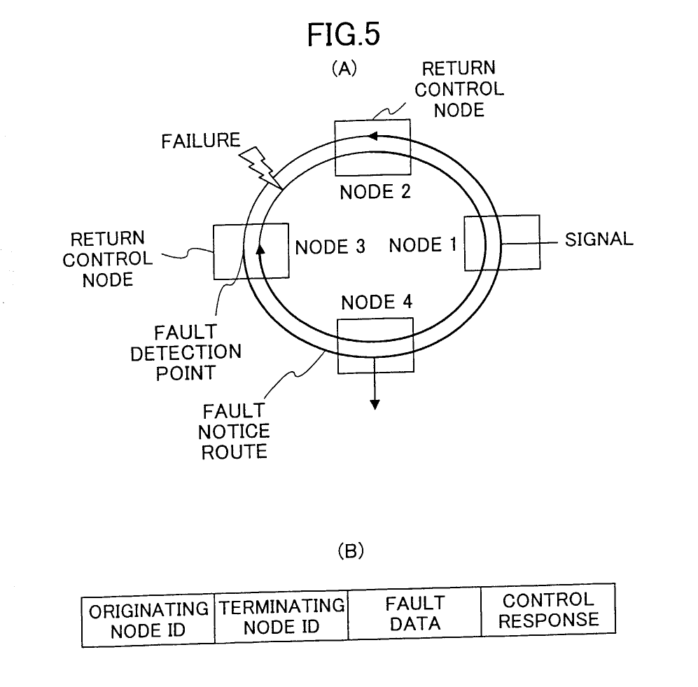

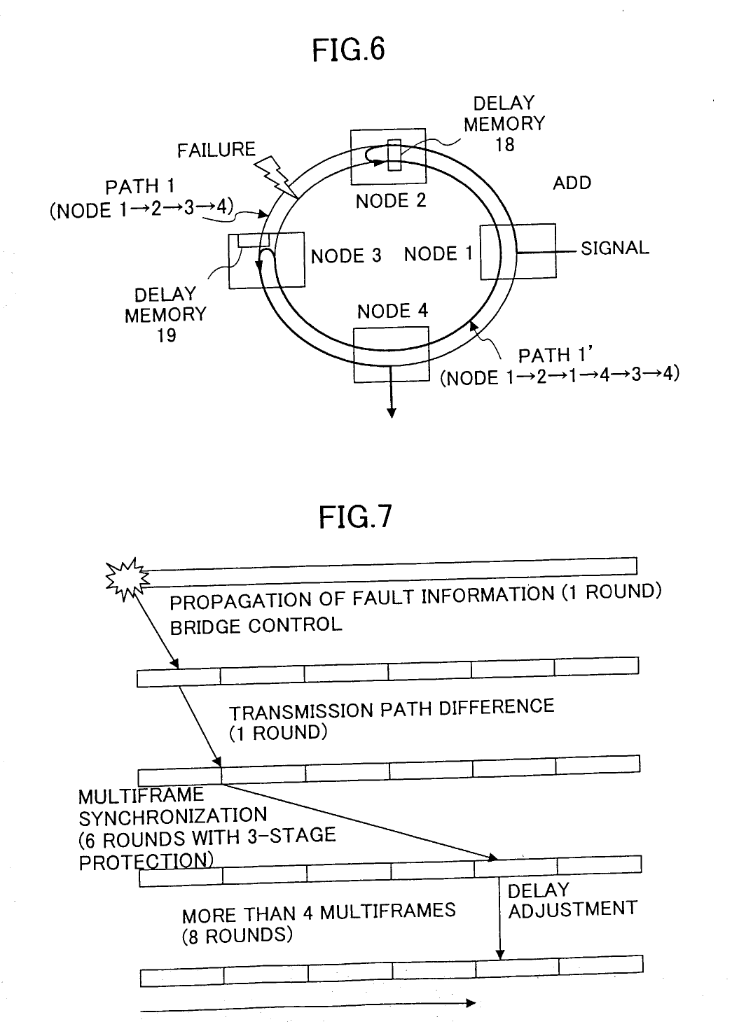

### DETAILED DESCRIPTION OF THE PREFERRED EMBODIMENTS

The invention will now be described in more detail with reference to the drawings.

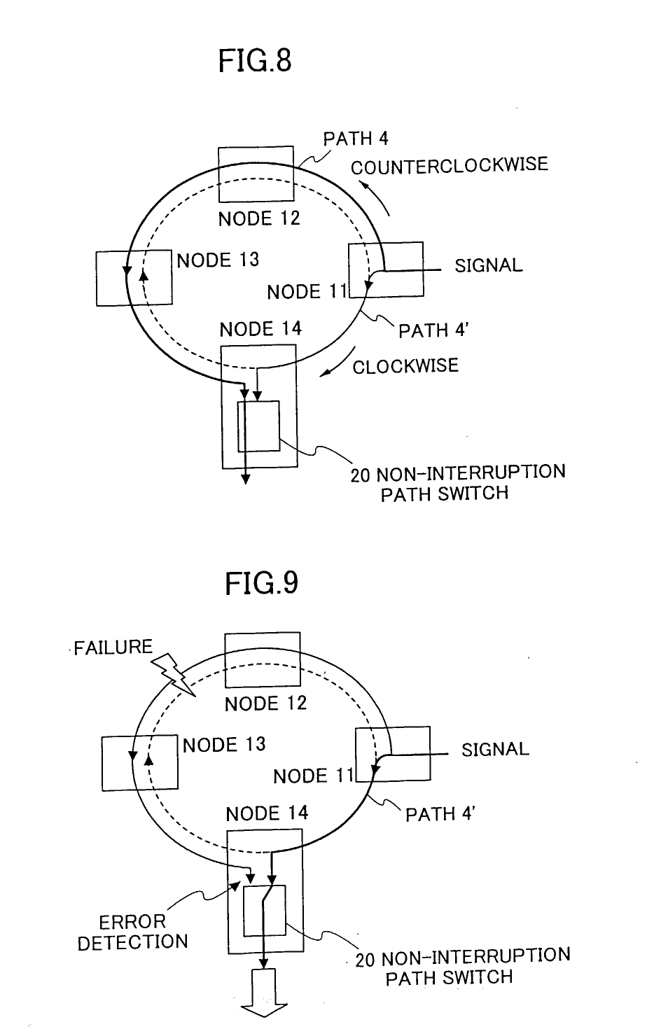

FIG. 8 illustrates a basic structure of the bidirectional line switched ring, showing the concept of the present invention. Nodes 11, 12, 13 and 14 constitute a ring. In the example shown in FIG. 8, node 11 is an add node through which a signal is inserted into the ring, and node 14 is a drop node from which the signal is extracted from the ring.

A counterclockwise path 4 extends from add node 11 to drop node 14 along a currently working line (normal route). A clockwise path 4′ also extends from add node 11 to drop node 14 along a protection line running in the opposite direction from the working line. The path 4 is protected by path 4′ and functions as a non-interruption path so that the service is maintained without interruption even at the time of a failure. The path 4′ functions as a fault bypass backup path to support the non-interruption path 4. The signal path is switched between path 4 and path 4′ at the drop node 14.

A signal received at node 11 is inserted (or added) into both the counterclockwise path 4 and clockwise path 4′ simultaneously. In FIG. 8, only a single channel (time slot) is illustrated for the sake of convenience. A phase identifier is given to the signals inserted into paths 4 and 4′ at the add node 11, so that uninterrupted path switching is appropriately carried out at the terminating (or destination) node 14.

Drop node 14 has a non-interruption path switch 20 that selects either counterclockwise path 4 or clockwise path 4′ to avoid a failure that occurs on the currently working line W. In the current state, the non-interruption path switch 20 is selecting the counterclockwise path 4 along the currently working line W.

If a failure occurs between node 12 and node 13, as illustrated in FIG. 9, then the drop node (i.e., node 14) detects the occurrence of failure on path 4, and switches the signal path from path 4 to path 4′ by the switching operation of the non-interruption path switch 20. At this point of time, the same signal that has been inserted at the add node 11 into path 4′ reaches the drop node (node 14).

In the system shown in FIG. 9, the same signal is inserted in both path 4 and path 4′, between which switching is carried out without interruption. This path switching is unidirectional path switching generally used in a UPSR system. The path difference between the counterclockwise path 4 and the clockwise paths 4′ is much less than one time around the ring, and the drop node (node 14) only needs to absorb this amount of path difference. This arrangement allows the memory capacity of node 14 to be reduced greatly.

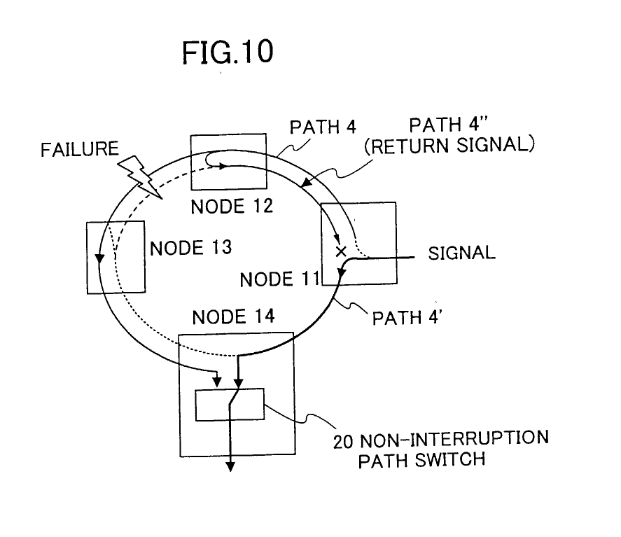

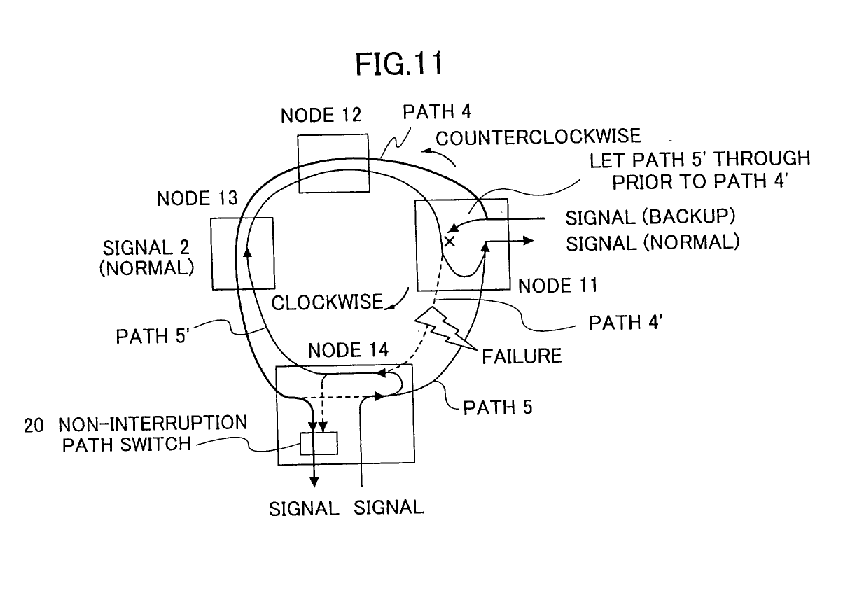

Then, as illustrated in FIG. 10, all the counterclockwise signal paths 4 extending from node 12 to node 13 are turned back at node 12 in the opposite direction using an ordinary BLSR method, and then follow the clockwise path 4″ along the protection line P. All the return paths 4″, except for the time slot corresponding to the fault bypass backup path 4′, pass through the add node 11 and can reach the destination node 14. Since the same signals have already been added to the clockwise path 4′, the return path time slot that corresponds to the clockwise path 4′ is discarded, while signals are continuously added to path 4′ in this time slot. In this manner, uninterrupted path switching is realized using a combination of unidirectional path switching and bidirectional line switching, without service interruption or without increase of memory capacity.

Next, FIG. 11 illustrates another example of fault occurrence. In FIG. 11, a failure occurs between node 11 and node 14. The non-interruption path switch 20 has been selecting the counterclockwise path 4 before the occurrence of the failure. This failure does not directly affect the forwarding path 4 to node 14, and therefore, no switching is conducted at the non-interruption path switch 20. However, in order to save the other signal paths passing through the fault section, bidirectional line switching starts automatically for the other time slots. In other words, a bridging operation for turning all the counterclockwise paths back to clockwise paths is carried out at node 14. For this example, it is assumed that a different signal is supplied on path 5 extending from node 14 to node 11.

Because clockwise path 4′ has already been inserted in the time slot that is supposed to be used as a protection path for signal path 5, path 5′ cannot pass through to node 14. To overcome this problem, node 11 detects the occurrence of the bidirectional line switching that has started at node 14 to save the other signal paths, and upon detection, node 11 releases the time stop in which the fault bypass backup path 4′ has been inserted, and set up the through mode for the return path 5′. The released time slot is now available for the return path 5′.

In this manner, assignment of time slots is carried out in common between the UPSR method and the BLSR method. In other words, all the time slots are available for this BLSR system, and at the same time, a signal path is switchable between the non-interruption path 4 along the currently working line W and the fault bypass backup path 4′ along the protection line P based on the UPSR method, for each time slot.

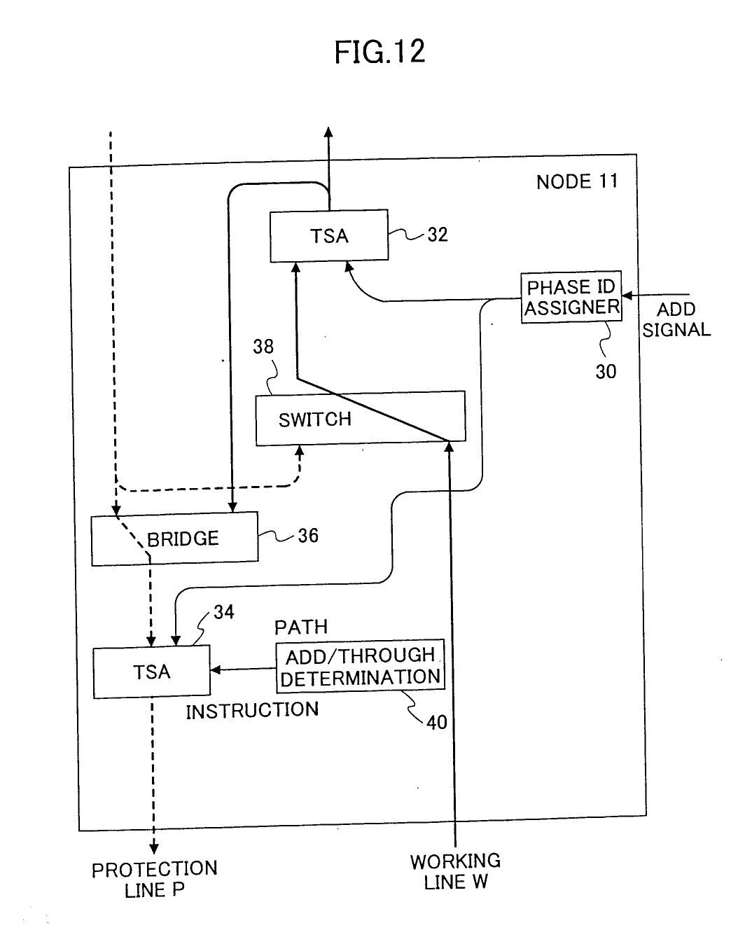

FIG. 12 illustrates an example of the add node (node 11) used in the BLSR system according to the first embodiment of the invention. In general, each of the nodes 11-14 has all the functions required of an add node, a drop node, and a through node.

In FIG. 12, add node 11 has a phase ID assigner 30 that gives a phase identifier to the signal to be added. Add node 11 also has a first TSA (Time Slot Assignment) 32 that assigns a time slot to the signal supplied to the currently working line W, and a second TSA 34 that also assigns a time slot to the same signal supplied to the protection line P. Accordingly, signals with a phase ID are inserted simultaneously in the designated time slots of the working line W and the protection line P. These time slots make a pair. The TSA units 32 and 34 carry out switching operations including insertion and extraction of time slots.

The output from the first TSA 32 is supplied to the forward node (i.e., node 12 in the examples shown in FIGS. 8-11) through the currently working line W. The output of the first TSA 32 also supplied to bridge 36. Bridge 36 turns the signal propagating through the currently working line W back into the corresponding time slot of the protection line P. The bridge 36 is positioned before the second TSA 34. The signals that have passed through the bridge 36 are supplied to the backward node (i.e., node 14 in the examples shown in FIGS. 8-11) via the second TSA 34. On the other hand, switch 38 switches the signals between the currently working line W and the protection line P. Those signals that pass through the switch 38 are supplied to the forward node (i.e., node 12) via the first TSA 32.

The add node 11 further has an add/through determination unit 40. The add/through determination unit 40 determines whether the new signal with the phase ID should be added to the protection line P (as a fault bypass backup path), or the signal (or data) having passed through the bridge 36 on the return path along the protection line P should be supplied through to the drop node 14. Based on the determination result, an instruction is supplied to the second TSA 34, and the second TSA 34 switches the operation mode between ADD and THROUGH.

The through nodes 12 and 13 have the same structure as the add node 11, except for the first and second TSA 32 and 34 that are always set to the through mode in nodes 12 and 13, respectively.

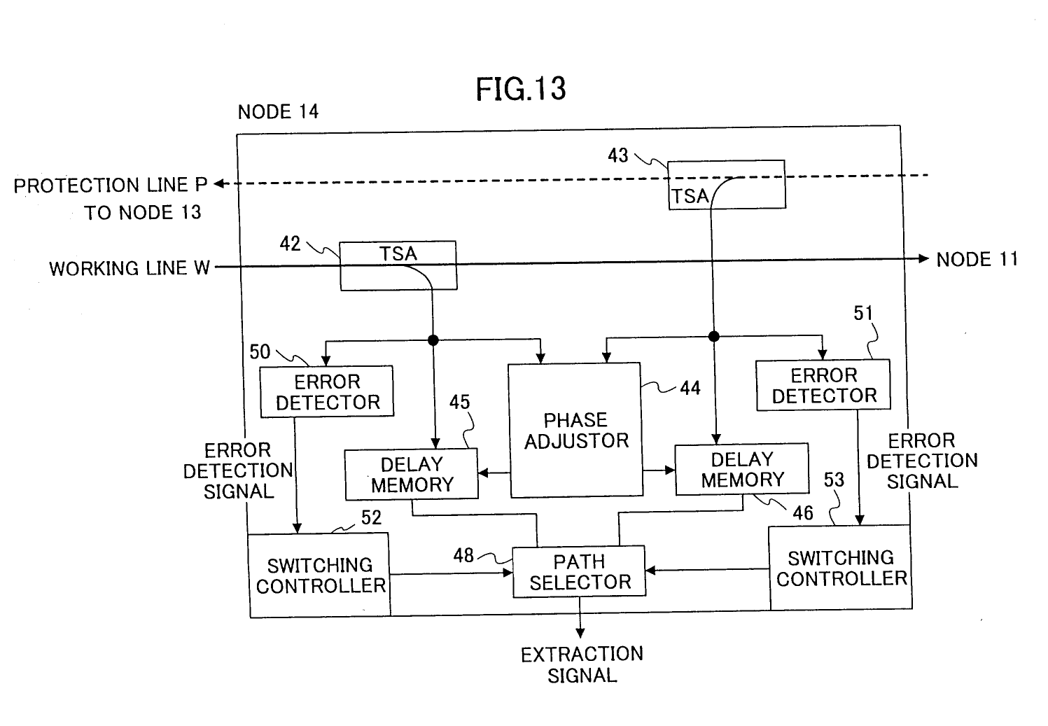

FIG. 13 illustrates an example of the drop node (node 14) in the BLSR system according to the first embodiment. The drop node 14 has a first TSA 42 that extracts the signal from the currently working line W, and a second TSA 43 that extracts the same signal from the protection line P via the switching operation. A phase adjustor 44 examines the phases of the extracted signals based on the phase identifiers and determines how much the delay amount be adjusted. The phase adjustor 44 supplies an instruction to the first delay memory 45 for the working line W and to the second delay memory 46 for the protection line P. The first and second delay memories 45 and 46 adjust the delays of the extracted signals. A path selector 48 selects a signal either from the first delay memory 45 or the second delay memory 46.

The drop node 14 also has first and second error detectors 50 and 51, which detect errors in the currently working line W and the protection line P, respectively. The error signals output from the first and second error detectors 50 and 51 are supplied to the first and second switching controllers 52 and 53, respectively. The switching controllers 52 and 53 control the switching operation of the path selector 48.

In the normal operation, the path selector 48 selects the signal extracted from the currently working line W. If the first error detector 50 detects any error on the working line W, then the switching controller 52 causes the path selector 48 to select the signal from the protection line P.

Thus, in the first embodiment, the add node 11 has features of both BLSR and UPSR, while the drop node 14 has a feature of UPSR. The through nodes 12′ and 13 have features of BLSR.

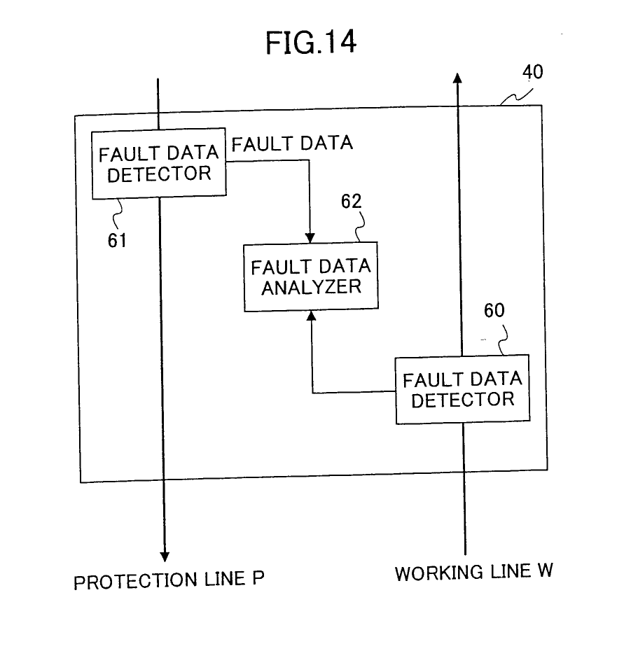

FIG. 14 illustrates an example of the add/through determination unit 40 in the add node 11 (FIG. 12). The add/through determination unit 40 has a first fault-data detector 60 for detecting fault information propagating through the currently working line W, a second fault-data detector 61 for detecting fault information propagating through the protection line P, and a fault data analyzer 62. The fault data from the working line W and the protection line P are necessary to carry out bidirectional line switching. The fault data analyzer 62 receives fault data from the first and second fault-data detectors 60 and 61yzer 62, and determines whether or not the non-interruption path designated by the local station (i.e., add node 11) passes through the fault section.

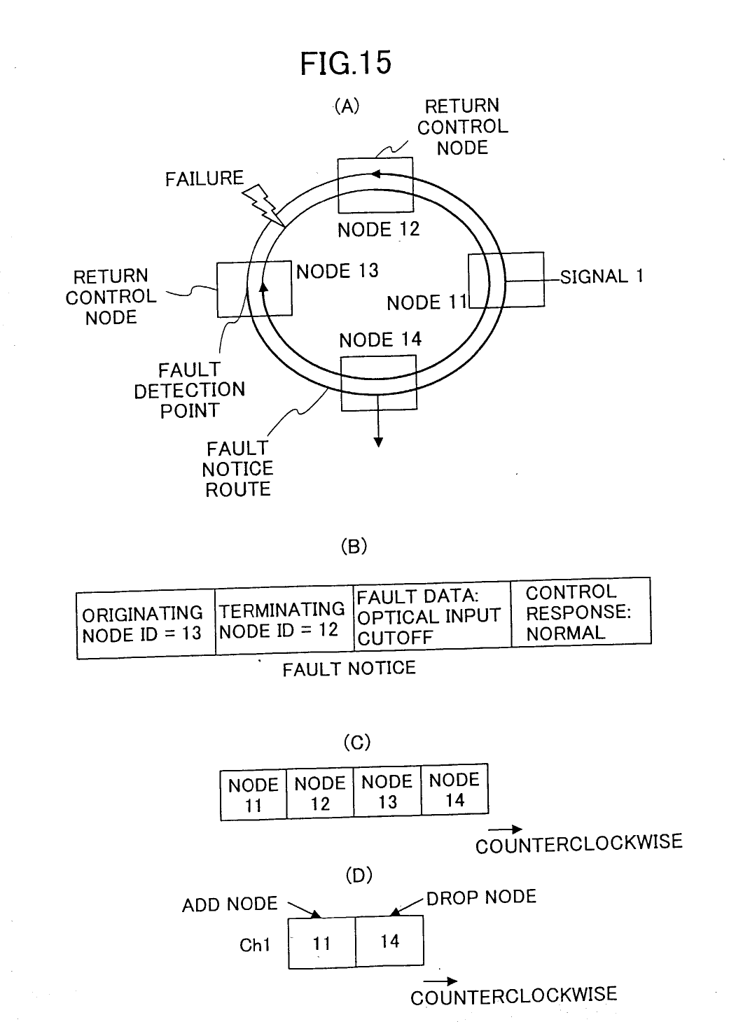

FIG. 15(A) illustrates propagation of fault information. Fault information is supplied from a node that detects a failure (e.g., node 13 in the example of FIG. 15(A)) to a node that needs to be informed of the failure (e.g., node 12). FIG. 15(B) illustrates an example of the fault information. The fault information includes an originating (or source) node ID that detects the failure, a terminating (or destination) node ID to which the fault information is to be provided, fault data (such as cutoff of optical input, deterioration of transmission line, need for manual switching, restoration of service, need for manual switch-back, etc.), and control response (such as measures taken against-the fault, completion of the measures, unavailability of restoration, etc).

The terminating (or destination) node 12 is generally an adjacent node that shares the fault section with the detecting (originating) node 13. Node 13 and node 12 function as return control nodes, and the fault information is transferred between these nodes through a return path in order to carry out BLSR operations. In a conventional BLSR system, relay nodes whose node IDs are different from either the originating node ID or the terminating node ID do not take any specific actions. In contrast, add node 11 of this embodiment makes use of the fault information for the add/through determination.

As described above, the fault information detected at the fault data detector 60 or 61 (FIG. 14) of the add/through determination unit 40 is supplied to the fault data analyzer 62. The fault data analyzer 62 determines whether or not the non-interruption path designated by the add node 11 passes through the fault section. This determination requires additional information other than the fault information. That is, information as to the node configuration or sequence is required. Such node information is stored in each node when the ring is constituted. An example of node information is shown in FIG. 15(C). Path information, an example of which is shown in FIG. 15(D), is also required. The pass information indicates which time slots (i.e., channels) on the ring are used between what nodes in association with the node IDs. The example illustrated in FIG. 15(D) indicates that the time slot of channel 1 is assigned between add node 11 and drop node 14. The path connection information is given to the respective nodes when a path is opened. Node information and path information are indispensable for the BLSR system.

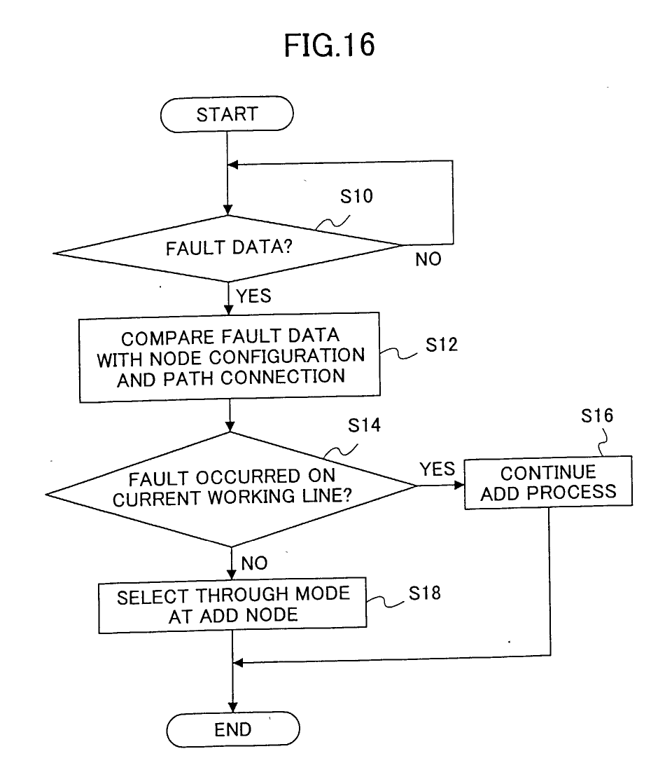

FIG. 16 is an operation flow of the add/through determination carried out by the fault data analyzer 62. First, in step S10, the fault data analyzer 62 monitors fault information constantly to determine if a fault has been detected. If a fault has been detected (YES in S10), the fault information is compared with the node configuration and the path connection in step S12.

The fault information is compared with the node configuration in order to identify at which section the failure occurred. Then, the path information is referred to in order to determine in step S14 whether the non-interruption path designated by the add node 11 passes through the fault section. If the non-interruption path along the currently working line W passes through the fault section (YES in S14), the process proceeds to step S16, in which add operation is continuously carried out, and signals are continuously added to the fault bypass path along the protection line P. If the non-interruption path does not pass through the fault section (NO in S14), then the process proceeds to step S18, in which the mode of the second TSA 34 is switched to the through mode in order to save the return path along the protection line P.

By the way, only a single non-interruption path is established in each time slot, and therefore, if a non-interruption path has already been established in a certain time slot by a node, the other nodes on the ring cannot establish a new non-interruption path in that time slot. Or even if a new non-interruption path may be established, uninterrupted path switching can not be guaranteed. For this reason, it is necessary to control establishment of a new non-interruption path. To this end, a path connection management table is used in the first embodiment.

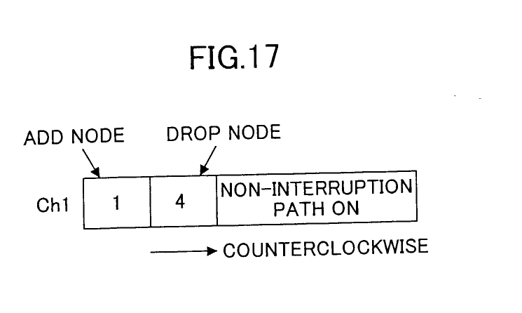

FIG. 17 illustrates an example of the path connection management table. The path connection management table stores the path connection relationship and a non-interruption path flag for indicating whether or not the path is set up as a non-interruption path in that channel (i.e., time slot). In the example of FIG. 17, the time slot of channel 1 is added at node 11 and dropped at node 14. This path is set up as a non-interruption path because the flag is ON. A path connection management table is provided to each node. If the non-interruption path flag is ON, no other non-interruption path is established in the same time slot.

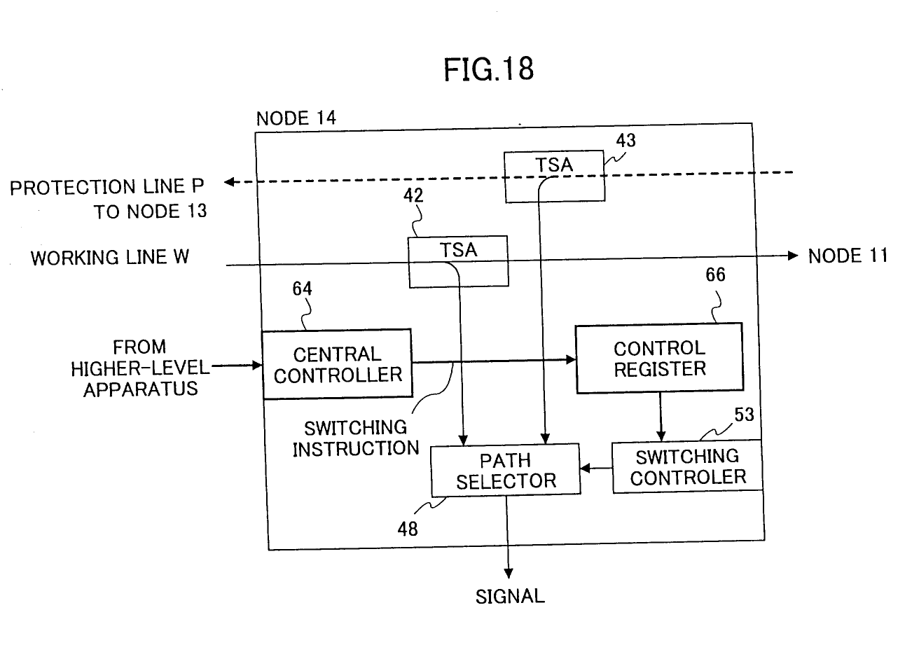

FIG. 18 illustrates a structure of the drop node 14 according to the second embodiment of the invention, which can deal with a manual switching command supplied from a higher-level apparatus (such as a maintenance work station).

In the first embodiment, switching of the non-interruption path is automatically controlled at the drop node 14, based on whether a fault occurs on the transmission line. However, the higher-level apparatus (e.g., a maintenance work station) carries out manual switching of the ring for the purpose of replacing the optical fiber between nodes or establishing a new node. In this case, only the target node at which bridging and switching are conducted is subjected to manual control. In parallel to the manual switching control, non-interruption path switching may also be required due to a failure on the transmission line. Therefore, in the second embodiment, how to handle the control of the non-interruption path switching under the manual switching command from the higher-level apparatus will be explained.

The drop node 14 illustrated in FIG. 18 includes a central controller 64 that receives a manual switch command from the higher-level apparatus (not shown) and generates a switching instruction, and a control register 66 that receives and stores the switching instruction generated by the central controller 64. The drop node 14 also has a first TSA provided for the currently working line W, a second TSA provided for the protection line P, and a path selector 48 that selects and outputs one of the signals from the first TSA 42 and the second TSA 43. A switching controller 53 controls the switching operation of the path selector 48 based on the switching instruction stored in the control register 66.

In this manner, a control register 66 that holds the switching instruction having a value corresponding to the manual switching command is provided to the drop node 14 that carries out non-interruption path switching. Based on the switching instruction, a path specified by the higher-level apparatus is appropriately selected even at the drop node 14 that conducts non-interruption path switching.

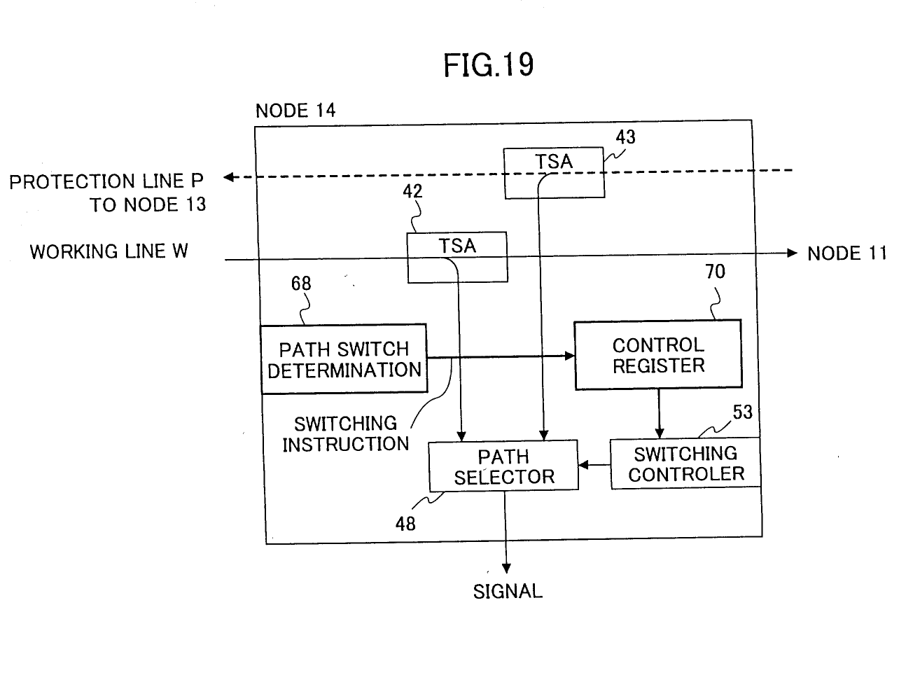

FIG. 19 illustrates a structure of the drop node 14 according to the third embodiment of the invention. In the third embodiment, necessity for path switching is determined based on BLSR fault information that contains a manual switch command, instead of receiving the command directly from the higher-level apparatus. The drop node 14 includes a path switch determination unit 68 and a control register 70. The path switch determination unit 68 determines whether or not a manual switch command is contained in the fault information, and if so, generates a switching instruction. The control register 70 stores the switching instruction output from the path switch determination unit 68. The remaining structure of the drop node 14 is the same as that in the second embodiment and explanation for them is omitted.

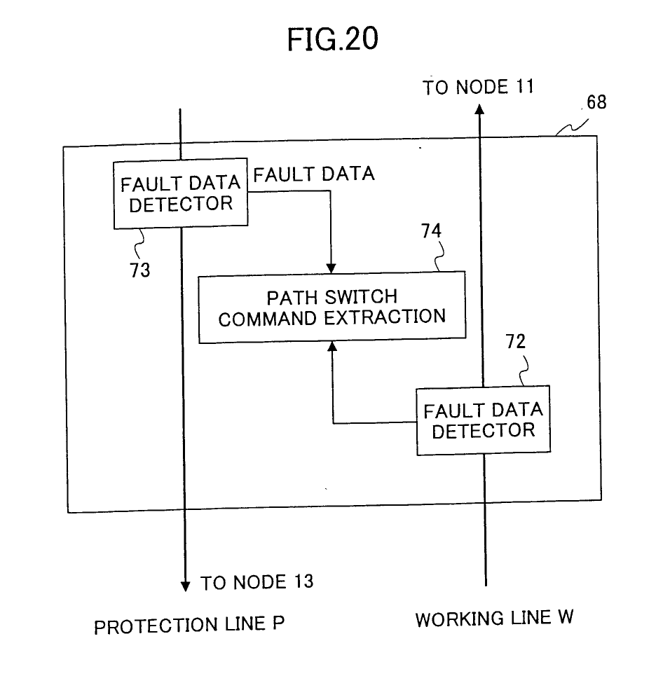

FIG. 20 illustrates an example of the path switch determination unit 69. The path switch determination unit 69 includes a first fault data detector 72 detecting fault data propagating through the currently working line W, a second fault data detector 73 detecting fault data propagating through the protection line P, and a path switch command extraction unit 74. The fault information is similar to that shown in FIG. 15(B), but additionally contains a manual switch command generated by a higher-level apparatus. The path switch command extraction unit 74 generates a switching instruction based on the manual switch command contained in the fault data.

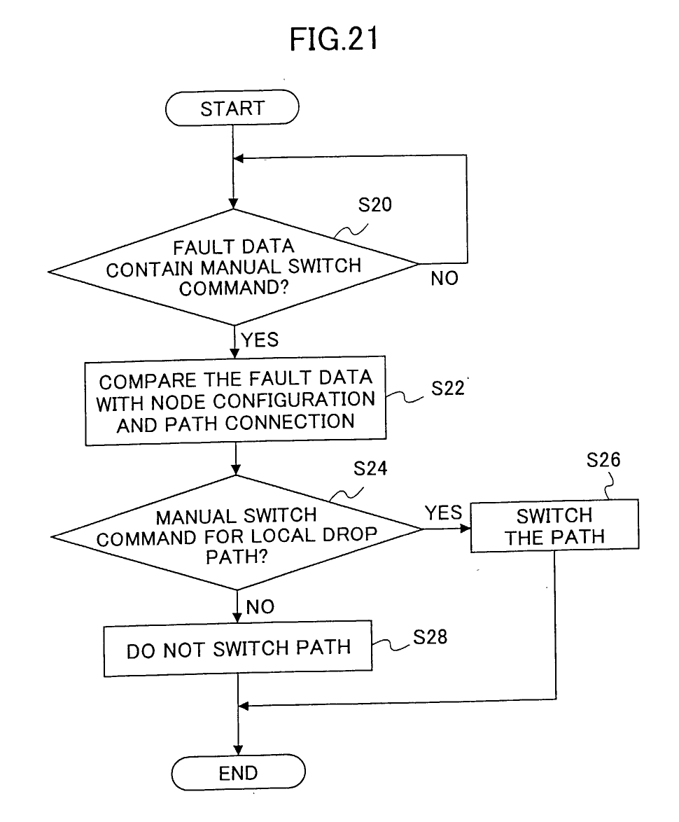

FIG. 21 illustrates an operation flow of the path switch command extraction unit 74. In step S20, the path switch command extraction unit 74 constantly monitors the fault information detected by the first fault data detector 72 and the second fault data detector 73, and determines whether the fault data contains a manual switch command. If there is a manual switch command contained in the detected fault data (YES in S20), the fault information is compared with the node configuration and the path connection in step S22. Then, in step S24, it is determined whether the manual switch command is addressed to the non-interruption local drop path. If the manual switch command is for this non-interruption local drop path (YES in S24), the process proceeds to step S26, in which the path is switched. If the manual switch command is not addressed to the non-interruption local drop path (NO in S24), the process proceeds to step S28, in which path switching is not carried out.

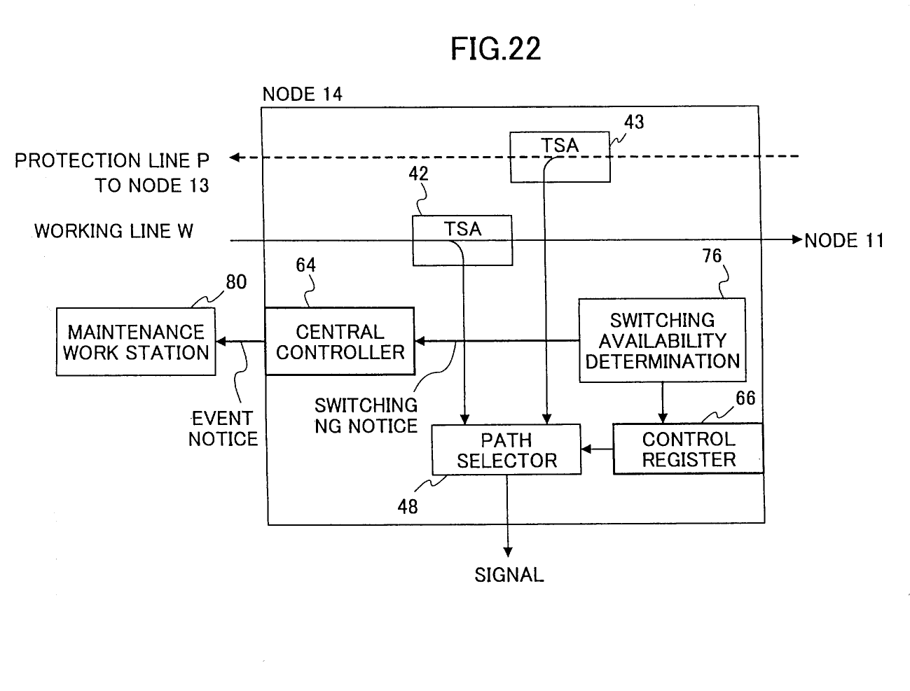

FIG. 22 illustrates a structure of the drop node 14 according to the fourth embodiment of the invention. In the fourth embodiment, the drop node 14 is capable of providing availability information of non-interruption path switching to the higher-level apparatus (or a maintenance operator). If bidirectional line switching is now occurring in the BLSR system, and if a failure occurs during this bidirectional line switching, then uninterrupted path switching cannot be guaranteed even if the bidirectional line switching is irrelevant to the non-interruption path dropped at node 14. To overcome this problem, the drop node 14 has a function of informing the higher-level apparatus (or maintenance operator) about switching availability.

To realize this function, the drop node 14 has a switching availability determination unit 76 that determines whether or not path switching is available for the non-interruption local drop path. If uninterrupted path switching is unavailable for this non-interruption path, a switching NG (negative) notice is generated and supplied to the central controller 64. At the same time, the determination result is supplied to control register 66. The central controller 64 generates an event notice, and transmits this notice to the higher-level apparatus (such as a maintenance work station), indicating unavailability of uninterrupted path switching. The control register 66 controls the switching operation of the path selector 48 based on the determination result.

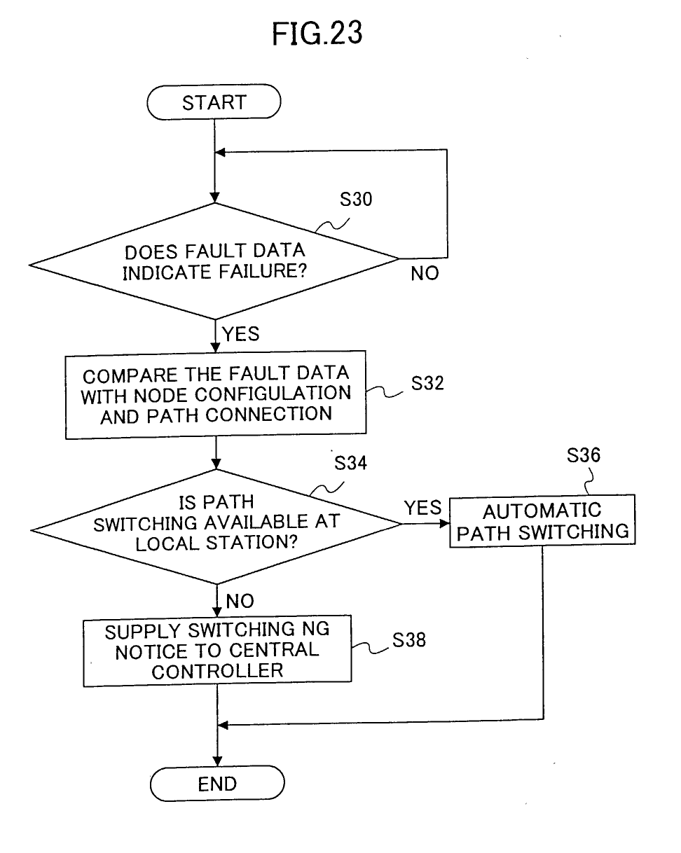

FIG. 23 illustrates an operation flow of the switching availability determination unit 76. In step S30, the switching availability determination unit 76 constantly monitors fault information, and determines whether or not the fault information indicates an occurrence of failure. If a failure occurs (YES in S30), the fault information is compared with the node configuration and the path connection in step S32. Then, in step S34, it is determined whether or not uninterrupted path switching is available at the local drop node 14. If bidirectional line switching is being carried out at another node, uninterrupted path switching is unavailable at drop node 14. If no bidirectional line switching is occurring at any other nodes, then uninterrupted path switching is available at drop node 14. If uninterrupted path switching is available (YES in S34), the process proceeds to step S36, in which the signal path is automatically switched to the fault bypass path. If uninterrupted path switching is unavailable (NO in S34), then the process proceeds to step S38, in which a switching NG (negative) notice is supplied to the central controller 64.

In uninterrupted path switching of the present invention, the path selector 48 of the drop node 14 has to switch the path back to the normal route after the failure is fixed. Accordingly, the drop node 14 has to know about restoration of the failure and termination of the BLSR switch-back operation.

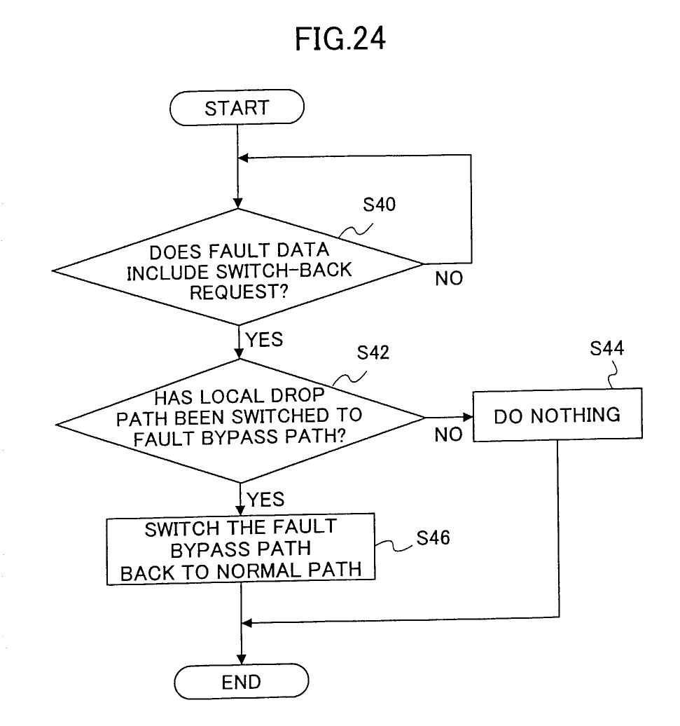

FIG. 24 illustrates an operation flow of the switching controller 53 of drop node 14. In step S40, it is determined whether or not a switch-back request is contained in the fault data. If a switch-back request is contained in the fault data (YES in S40), then it is further determined in step S42 whether or not the non-interruption path has been switched to the fault bypass path at the drop node 14. If the fault bypass path is not selected at the drop node 14, the process proceeds to S44, and nothing takes place. If the fault bypass path is presently selected at drop node 14, then the process proceeds to step S46, and the signal path is switched back to the normal route (i.e., the non-interruption path).

With the BLSR system of the invention, the second TSA 34 (for the protection line P) of the add node 11 is set to the through mode during bidirectional line switching irrelevant to the non-interruption path, as has been explained above in conjunction with FIGS. 11 and 12. However, once the failure is fixed, a signal is added again to the protection line P at the add node 11. This add/through switching after the restoration is also carried out by the add/through determination unit 40 (FIG. 12).

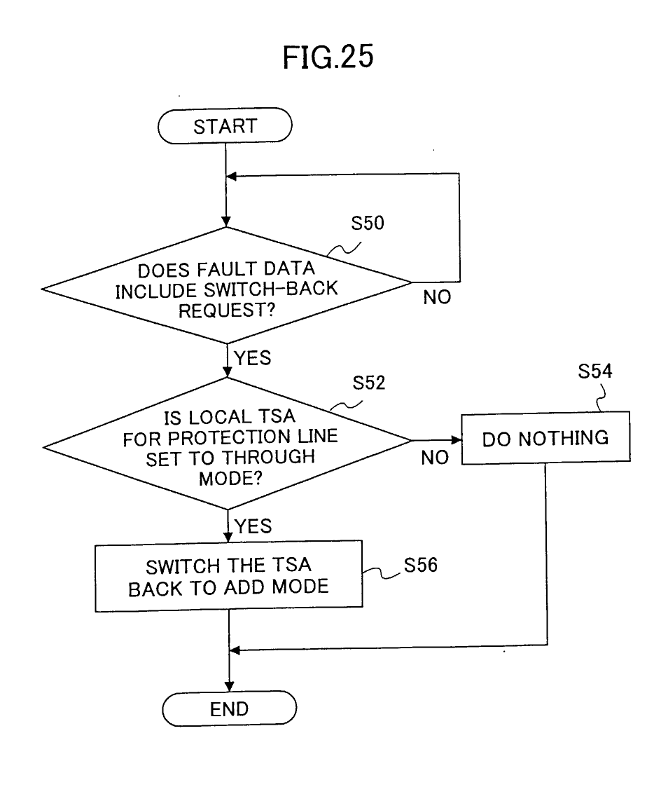

FIG. 25 illustrates an operation flow of switching back to the add mode after restoration of failure. In step S50, the add/through determination unit 40 determines whether or not the fault information contains a switch back request. If there is a switch back request contained in the fault information (YES in S50), then it is further determined in step S52 whether the second TSA 34 for the protection line is set to the through mode at the local add node 11. If the second TSA 34 is not set to the through mode (NO in S52), it means that the second TSA 34 is in the add mode, and therefore, no action is taken in step S54. If the second TSA 34 is in the through mode, then the operation of the second TSA 34 is switched back to the add mode and a signal is added to the fault bypass path of the protection line P in step S56.

The present invention is not limited to these embodiments, but various variations and modifications may be made without departing from the scope of the present invention.

What is claimed is:

1. A switching method for an optical ring, comprising the steps of:
establishing a non-interruption path along a currently working line, the non-interruption path extending from an add node from which a signal is inserted into the ring to a drop node from which the signal is extracted from the ring;
establishing a fault bypass backup path along a protection line running in the opposite direction from the currently working line, the fault bypass backup path extending from the add node to the drop node;
inserting the signal from the add node into both the currently working line and the protection line;
determining whether a failure occurs on the currently working line; and
selecting the fault bypass backup path and extracting the signal having propagating through the protection line at the drop node if a failure occurs on the currently working line.

2. The method according to claim 1, further comprising the step of giving a phase identifier to the signals inserted into the currently working line and the protection line at the add node.

3. The method according to claim 1, further comprising the steps of:
switching a signal path back to the currently working line if the failure is restored; and
extracting the signal having propagated through the currently working line at the drop node.

4. The method according to claim 1, wherein only a single non-interruption path is established for each time slot, and the method further comprising the step of:
controlling establishment of the non-interruption path using a path connection management table.

5. The method according to claim 1, further comprising the steps of:
determining whether a manual switching command is received in the ring;
determining whether the manual switching command is addressed to the non-interruption path if the manual switching command is received; and
switching a signal path from the currently working line to the protection line if the manual command is addressed to the non-interruption path.

6. The method according to claim 1, further comprising the steps of:
determining if path switching of the non-interruption path is available; and
providing a notification of unavailability of path switching of the non-interruption path if the path switching is not available.

7. A switching method for an optical ring, comprising the steps of:
establishing a non-interruption path along a currently working line, the non-interruption path extending from an add node from which a signal is inserted into the ring to a drop node from which the signal is extracted from the ring;
establishing a fault bypass backup path along a protection line running in the opposite direction from the currently working line, the fault bypass backup path extending from the add node to the drop node;
inserting the signal from the add node into both the currently working line and the protection line;
determining whether a failure detected in the ring is relevant to the non-interruption path; and
continuously inserting the signal from the add node into the protection line if the failure is relevant to the non-interruption path.

8. The method according to claim 7, further comprising the step of:
switching a signal path from the non-interruption path to the fault bypass backup path at the drop node if the failure is relevant to the non-interruption path.

9. A switching method for an optical ring, comprising the steps of:
establishing a non-interruption path along a currently working line, the non-interruption path extending from an add node from which a signal is inserted into the ring to a drop node from which the signal is extracted from the ring;
establishing a fault bypass backup path along a protection line running in the opposite direction from the currently working line, the fault bypass backup path extending from the add node to the drop node;
inserting the signal from the add node into both the currently working line and the protection line;
determining whether a failure detected in the ring is relevant to the non-interruption path; and
allowing a return path entering the add node along the protection line to pass through the add node, instead of adding the signal to the protection line if the failure is irrelevant to the non-interruption path.

10. The method according to claim 9, further comprising the steps of:
continuing to select the non-interruption path at the drop node if the failure is irrelevant to the non-interruption path, and returning other signal paths to produce the return path along the protection line.

11. The method according to claim 9, further comprising the step of:
resuming adding the signal to the protection line, instead of allowing the return path to pass through the add node, if the failure is restored.

12. A bidirectional line switched ring comprising:
an add node from which a signal is added to the ring;
a drop node from which the signal is extracted from the ring;
a non-interruption path extending from the add node to the drop node along a currently working line; and
a fault bypass backup path extending from the add node to the drop node along a protection line running in the opposite direction from the currently working line,
the add node being configured to add the signal to both the currently working line and the protection line, the add node having an add/through determination unit configured to determined whether or not a failure occurs on the non-interruption path and to continuously add the signal to the protection line if the failure has occurred on the non-interruption path.

13. The bidirectional line switched ring according to claim 12, wherein the drop node has a path selector configured to select the fault bypass backup path if the failure has occurred on the non-interruption path.

14. The bidirectional line switched ring according to claim 12, wherein the add/through determination unit allows a return path entering the add node along the protection line to pass through the add node if the failure is irrelevant to the non-interruption path.

15. An add node used in an optical ring having a currently working line and a protection line running in the opposite direction from the currently working line, the add node being configured to add a signal to the optical ring and comprising:
a first time slot assignment unit provided for the currently working line and configured to assign a first time slot to the signal so as to allow the signal to be added to the currently working line;
a second time slot assignment unit provided for the protection line and configured to assign a second time slot corresponding to the first time slot to the signal so as to allow the signal to be added to the protection line; and
an add/through determination unit configured to determined whether or not a failure occurs on the currently working line extending from the add node to a drop node and to continuously add the signal to the protection line if the failure occurs on the currently working line from the add node to the drop node.

16. The add node according to claim 15, wherein the second time slot assignment unit allows a return path entering the add node along the protection line to pass through the add node if the determination result of the add/through determination unit is negative.

17. The add node according to claim 15, further comprising a phase ID assigner configured to assign a phase ID to the signal to be added to the currently running line and the signal to be added to the protection line.

18. A bidirectional line switched ring comprising:
an add node from which a signal is added to the ring;
a drop node from which the signal is extracted from the ring;
a currently working line extending from the add node to the drop node; and
a protection line extending from the add node to the drop node running in the opposite direction from the currently working line, the add node being configured to add the signal to both the currently working line and the protection line, and
the drop node having:
a first error detector configured to detect an error on the currently working line;
a second error detector configured to detect an error on the protection line;
a path selector configured to receive the signal having propagating through the currently working line and the signal having propagating through the protection line and select one of the signals based on the error detection results of the first and second error detectors.

19. The bidirectional line switched ring according to claim 18, wherein the path selector selects the signal having propagating through the protection line if the first error detector detects the error on the currently working line.

20. A bidirectional line switched ring comprising:
an add node from which a signal is added to the ring;
a drop node from which the signal is extracted from the ring;
a non-interruption path extending from the add node to the drop node along a currently working line; and
a fault bypass backup path extending from the add node to the drop node along a protection line running in the opposite direction from the currently working line,
the add node being configured to add the signal to both the currently working line and the protection line, and
the drop node having:
a central controller configured to receive a manual switching command from an external higher-level apparatus and to generate a switching instruction;
a path selector configured to receive the signal from the non-interruption path and the signal from the fault bypass backup path and to select one of the signals; and
a switching controller configured to control a switching operation of the path selector based on the switching instruction.

21. A bidirectional line switched ring comprising:
an add node from which a signal is added to the ring;
a drop node from which the signal is extracted from the ring;
a non-interruption path extending from the add node to the drop node along a currently working line; and
a fault bypass backup path extending from the add node to the drop node along a protection line running in the opposite direction from the currently working line,
the add node being configured to add the signal to both the currently working line and the protection line, and
the drop node having:
a central controller configured to receive a manual switching command from an external higher-level apparatus and to generate a switching instruction;
a path selector configured to receive the signal from the non-interruption path and the signal from the fault bypass backup path and to select one of the signals; and
a switching availability determination unit configured to receive the switching instruction, determine if a switching operation of the path selector is available for the non-interruption path, and supply a switching negative signal to the central controller if the switching operation is unavailable.
